(19) United States
(12) Patent Application Publication
(10) Pub. No.: US 2026/0290488 A1
(43) Pub. Date: Sep. 24, 2026

(54) MEMORY SYSTEMS INCLUDING A SHARED WRITE/READ PARITY CIRCUIT

(71) Applicant: Micron Technology, Inc., Boise, ID (US)

(72) Inventor: Woo Hyun PAIK, Suwanee, GA (US)

(21) Appl. No.: 19/545,045

(22) Filed: Feb. 20, 2026

Related U.S. Application Data
(60) Provisional application No. 63/775,447, filed on Mar. 21, 2025.

(51) Int. Cl. G11C 29/52; G11C 11/4076; G11C 11/4096

(52) U.S. Cl. CPC G11C 29/52; G11C 11/4076; G11C 11/4096

(57) ABSTRACT

In some implementations, a memory system may receive, from a host system, a write command associated with a first set of data and a first set of parity information. The memory system may perform, using a shared write/read parity circuit of the memory system and the first set of parity information, a write parity check for the first set of data. The memory system may receive, from the host system, a read command associated with a second set of data and a second set of parity information. The memory system may perform, using the shared write/read parity circuit of the memory system and the second set of parity information, a read parity check for the second set of data.

### CROSS-REFERENCE TO RELATED APPLICATION

This Patent Application claims priority to U.S. Provisional Patent Application No. 63/775,447, filed on March 21, 2025, entitled “MEMORY SYSTEMS INCLUDING A SHARED WRITE/READ PARITY CIRCUIT,” and assigned to the assignee hereof. The disclosure of the prior Application is considered part of and is incorporated by reference into this Patent Application.

### TECHNICAL FIELD

The present disclosure generally relates to memory devices, memory device operations, and, for example, to memory systems including a shared write/read parity circuit.

### BACKGROUND

Memory devices are widely used to store information in various electronic devices. A memory device includes memory cells. A memory cell is an electronic circuit capable of being programmed to a data state of two or more data states. For example, a memory cell may be programmed to a data state that represents a single binary value, often denoted by a binary “1” or a binary “0.” As another example, a memory cell may be programmed to a data state that represents a fractional value (e.g., 0.5, 1.5, or the like). To store information, an electronic device may write to, or program, a set of memory cells. To access the stored information, the electronic device may read, or sense, the stored state from the set of memory cells.

Various types of memory devices exist, including random access memory (RAM), read only memory (ROM), dynamic RAM (DRAM), static RAM (SRAM), synchronous dynamic RAM (SDRAM), ferroelectric RAM (FeRAM), magnetic RAM (MRAM), resistive RAM (RRAM), holographic RAM (HRAM), flash memory (e.g., NAND memory and NOR memory), and others. A memory device may be volatile or non-volatile. Non-volatile memory (e.g., flash memory) can store data for extended periods of time even in the absence of an external power source. Volatile memory (e.g., DRAM) may lose stored data over time unless the volatile memory is refreshed by a power source. In some examples, a memory device may be associated with a high bandwidth memory (HBM) system. HBM is a high-speed memory interface for three-dimensional (3D)-stacked DRAM used in conjunction with high-performance graphics accelerators, network devices, and other high-performance computing applications. HBM achieves higher bandwidth while using less power in a substantially smaller form factor than traditional memory interfaces. This is accomplished by stacking multiple DRAM dies vertically and connecting them with an interposer, which allows for wider data paths and shorter distances for data to travel, resulting in increased speed and efficiency.

### BRIEF DESCRIPTION OF THE DRAWINGS

FIG. 1 is a diagram illustrating an example system capable of implementing a shared write/read parity circuit.

FIGS. 2A-2C are diagrams of examples associated with a memory system including separate write and read parity circuits.

FIGS. 3A-3D are diagrams associated with an HBM system including a shared write/read parity circuit.

FIG. 4 is a flowchart of an example method associated with memory systems including a shared write/read parity circuit.

### DETAILED DESCRIPTION

HBM systems may enable high-speed data transfer between a host and memory (e.g., DRAM). In order to maintain data integrity in such systems, HBM systems may use parity bits during both write and read operations. For example, the HBM systems may implement separate calculation blocks for write and read parity, each responsible for generating and comparing parity bits to ensure data reliability. These parity calculations may be used for detecting errors that may occur during the data transfer process. However, the design of these separate blocks for handling write and read parity introduces certain drawbacks in HBM systems.

For example, each parity calculation block occupies a substantial amount of silicon area within the already congested layout of the memory device. The space constraints are particularly acute in high-density integrated circuits, where the efficient use of area is paramount. Moreover, each block contributes to the overall power consumption of the device. For example, even when a block is not actively engaged in operations, the block may still draw a standby current, leading to increased power usage known as leakage. Moreover, the duplication of hardware for performing similar parity calculation operations results in redundancy in the memory system, unnecessarily increasing the overall cost of manufacturing the memory devices.

Some techniques and implementations described herein enable memory systems that employ an integrated approach to managing parity checks for write and read operations. In some implementations, a memory system (e.g., an HBM system) may include a shared write/read parity circuit for performing parity checks. In this way, when the memory system receives a write command, the memory system may execute a write parity check using the shared write/read parity circuit. On the other hand, when the memory system receives a read command, the memory system may execute a read parity check using the shared write/read parity circuit. In some aspects, the shared write/read parity circuit may be associated with multiplexers that are controlled by a read enable signal. In this way, upon assertion of the read enable signal, data associated with the read parity check may be routed through the shared write/read parity circuit, and, when the read enable signal is not asserted, data associated with the write parity check may be routed through the shared write/read parity circuit.

By consolidating the write and read parity check functions into a single shared circuit, the memory system addresses the problems of silicon area inefficiency and power wastage. The integration of previously separate parity check blocks for write and read operations into a shared circuitry results in a significant reduction of the silicon area footprint within the memory device. This is particularly advantageous for high-density integrated circuits where space conservation is important. Moreover, with a shared circuit for parity checks, the device’s overall power consumption is reduced due to a decrease in the number of components that draw standby current, thereby minimizing leakage.

In addition to reducing the overall power consumption by minimizing the number of components that draw standby current, the integration of the shared write/read parity circuit also addresses leakage power concerns. Even when individual circuit blocks are not actively engaged in write or read operations, they contribute to the total standby current, resulting in leakage power. By consolidating these blocks into a single shared circuit, the design ensures that fewer components contribute to leakage power, thereby significantly reducing the standby current in the HBM system. This reduction in leakage power further enhances the energy efficiency and overall power performance of the memory system.

In this way, the memory system described herein conserves processing resources and memory resources by minimizing hardware redundancy. The reduction in silicon area and power consumption may also lead to decreased manufacturing costs. The timing aspects described herein ensures that the parity checks for write and read operations are adequately segregated to prevent conflicts, thereby maintaining or improving data integrity and reliability. In this way, the quality and/or reliability of the memory system is improved. By improving the quality and/or the reliability of the memory system, an amount of resources used to support a market consuming the semiconductor device (e.g., raw materials, semiconductor manufacturing tools, labor, and/or computing resources) is reduced.

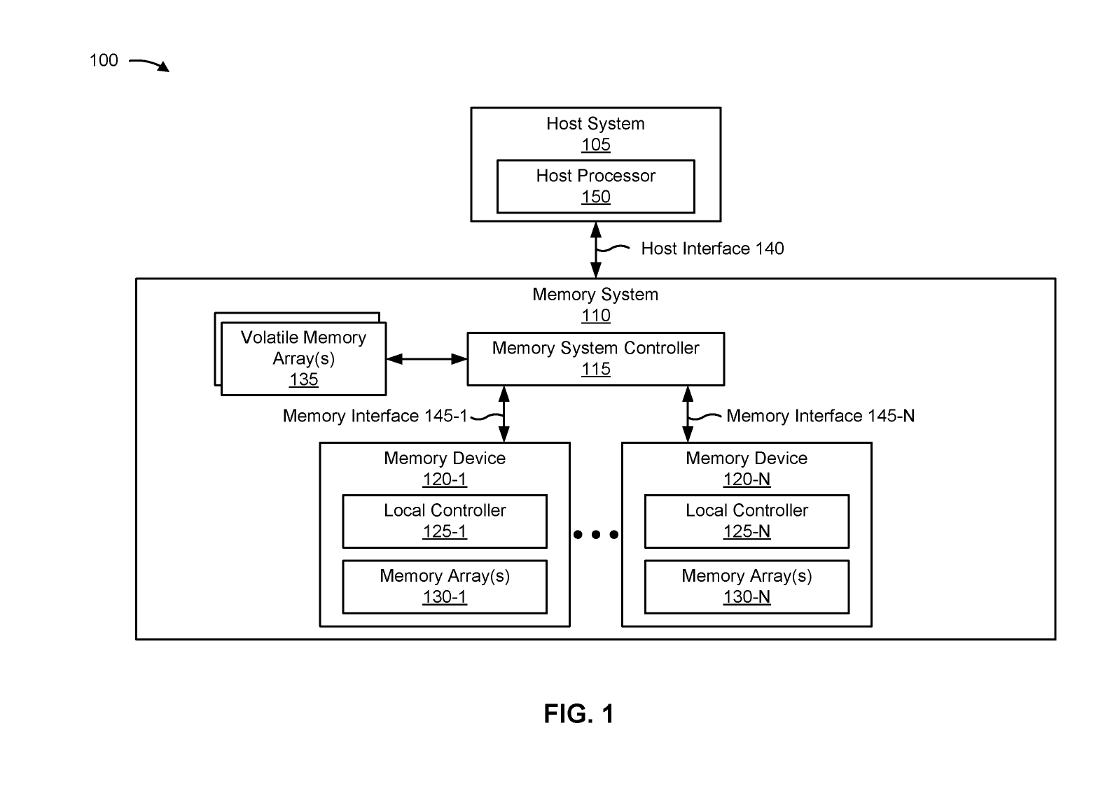

FIG. 1 is a diagram illustrating an example system 100 capable of implementing a shared write/read parity circuit. The system 100 may include one or more devices, apparatuses, and/or components for performing operations described herein. For example, the system 100 may include a host system 105 and a memory system 110. The memory system 110 may include a memory system controller 115 and one or more memory devices 120, shown as memory devices 120-1 through 120-N (where N ≥ 1). A memory device may include a local controller 125 and one or more memory arrays 130. The host system 105 may communicate with the memory system 110 (e.g., the memory system controller 115 of the memory system 110) via a host interface 140. The memory system controller 115 and the memory devices 120 may communicate via respective memory interfaces 145, shown as memory interfaces 145-1 through 145-N (where N ≥ 1).

The system 100 may be any electronic device configured to store data in memory. For example, the system 100 may be a computer, a mobile phone, a wired or wireless communication device, a network device, a server, a device in a data center, a device in a cloud computing environment, a vehicle (e.g., an automobile or an airplane), and/or an Internet of Things (IoT) device. The host system 105 may include a host processor 150. The host processor 150 may include one or more processors configured to execute instructions and store data in the memory system 110. For example, the host processor 150 may include a central processing unit (CPU), a graphics processing unit (GPU), a field-programmable gate array (FPGA), an application-specific integrated circuit (ASIC), and/or another type of processing component.

The memory system 110 may be any electronic device or apparatus configured to store data in memory. For example, the memory system 110 may be a hard drive, a solid-state drive (SSD), a flash memory system (e.g., a NAND flash memory system or a NOR flash memory system), a universal serial bus (USB) drive, a memory card (e.g., a secure digital (SD) card), a secondary storage device, a non-volatile memory express (NVMe) device, an embedded multimedia card (eMMC) device, a dual in-line memory module (DIMM), an HBM system, and/or a random-access memory (RAM) device, such as a dynamic RAM (DRAM) device or a static RAM (SRAM) device.

The memory system controller 115 may be any device configured to control operations of the memory system 110 and/or operations of the memory devices 120. For example, the memory system controller 115 may include control logic, a memory controller, a system controller, an ASIC, an FPGA, a processor, a microcontroller, and/or one or more processing components. In some implementations, the memory system controller 115 may communicate with the host system 105 and may instruct one or more memory devices 120 regarding memory operations to be performed by those one or more memory devices 120 based on one or more instructions from the host system 105. For example, the memory system controller 115 may provide instructions to a local controller 125 (e.g., via an HBM interface) regarding memory operations to be performed by the local controller 125 in connection with a corresponding memory device 120.

A memory device 120 may include a local controller 125 and one or more memory arrays 130. In some implementations, a memory device 120 includes a single memory array 130. In some implementations, each memory device 120 of the memory system 110 may be implemented in a separate semiconductor package or on a separate die that includes a respective local controller 125 and a respective memory array 130 of that memory device 120. The memory system 110 may include multiple memory devices 120.

A local controller 125 may be any device configured to control memory operations of a memory device 120 within which the local controller 125 is included (e.g., and not to control memory operations of other memory devices 120). For example, the local controller 125 may include control logic, a memory controller, a system controller, an ASIC, an FPGA, a processor, a microcontroller, and/or one or more processing components. In some implementations, the local controller 125 may communicate with the memory system controller 115 and may control operations performed on a memory array 130 coupled with the local controller 125 based on one or more instructions from the memory system controller 115. As an example, the memory system controller 115 may be an SSD controller, and the local controller 125 may be a NAND controller.

A memory array 130 may include an array of memory cells configured to store data. For example, a memory array 130 may include a non-volatile memory array (e.g., a NAND memory array or a NOR memory array) or a volatile memory array (e.g., an SRAM array or a DRAM array). In some implementations, the memory system 110 may include one or more volatile memory arrays 135. A volatile memory array 135 may include an SRAM array and/or a DRAM array, among other examples. The one or more volatile memory arrays 135 may be included in the memory system controller 115, in one or more memory devices 120, and/or in both the memory system controller 115 and one or more memory devices 120. In some implementations, the memory system 110 may include both non-volatile memory capable of maintaining stored data after the memory system 110 is powered off and volatile memory (e.g., a volatile memory array 135) that requires power to maintain stored data and that loses stored data after the memory system 110 is powered off. For example, a volatile memory array 135 may cache data read from or to be written to non-volatile memory, and/or may cache instructions to be executed by a controller of the memory system 110.

In some implementations, such as implementations involving HBM systems, a memory system 110 may include multiple stacked DRAM arrays or dies (e.g., 3D-stacked DRAM). More particularly, HBM DRAM consists of multiple DRAM dies stacked vertically on top of each other. These dies may be interconnected using through-silicon vias (TSVs), which are vertical electrical connections passing through the silicon dies. Each HBM stack typically contains multiple memory layers, with each layer consisting of DRAM cells. The number of layers can vary, with common configurations including 4-layer (HBM1), 8-layer (HBM2), and more.

In some examples, at a bottom of the HBM stack is the base logic die (e.g., local controller 125), which may act as an interface between the DRAM layers and the external memory controller (e.g., memory system controller 115). Additionally, or alternatively, the base logic die may handles memory management, data routing, and communication with the external components. In some examples, the HBM stacks may be mounted on a silicon interposer, which is a passive silicon substrate that provides electrical connections between the HBM stacks and the processor. The interposer may enable high-density, high-speed connections with minimal signal loss. Additionally, or alternatively, a memory controller of an HBM system (e.g., the memory system controller 115) may be responsible for managing data transfers between the HBM stacks and the processing cores. In some examples, the memory controller handles tasks such as memory addressing, data read/write operations, and error correction.

The host interface 140 enables communication between the host system 105 (e.g., the host processor 150) and the memory system 110 (e.g., the memory system controller 115). The host interface 140 may include, for example, a Small Computer System Interface (SCSI), a Serial-Attached SCSI (SAS), a Serial Advanced Technology Attachment (SATA) interface, a Peripheral Component Interconnect Express (PCIe) interface, an NVMe interface, a USB interface, a Universal Flash Storage (UFS) interface, an eMMC interface, a double data rate (DDR) interface, and/or a DIMM interface.

The memory interface 145 enables communication between the memory system 110 and the memory device 120. The memory interface 145 may include a non-volatile memory interface (e.g., for communicating with non-volatile memory), such as a NAND interface or a NOR interface. Additionally, or alternatively, the memory interface 145 may include a volatile memory interface (e.g., for communicating with volatile memory), such as a DDR interface. In some examples, the memory interface 145 may include an HBM interface.

Although the example memory system 110 described above includes a memory system controller 115, in some implementations, the memory system 110 does not include a memory system controller 115. For example, an external controller (e.g., included in the host system 105) and/or one or more local controllers 125 included in one or more corresponding memory devices 120 may perform the operations described herein as being performed by the memory system controller 115. Furthermore, as used herein, a “controller” may refer to the memory system controller 115, a local controller 125, or an external controller. In some implementations, a set of operations described herein as being performed by a controller may be performed by a single controller. For example, the entire set of operations may be performed by a single memory system controller 115, a single local controller 125, or a single external controller. Alternatively, a set of operations described herein as being performed by a controller may be performed by more than one controller. For example, a first subset of the operations may be performed by the memory system controller 115 and a second subset of the operations may be performed by a local controller 125. Furthermore, the term “memory apparatus” may refer to the memory system 110 or a memory device 120, depending on the context.

A controller (e.g., the memory system controller 115, a local controller 125, or an external controller) may control operations performed on memory (e.g., a memory array 130), such as by executing one or more instructions. For example, the memory system 110 and/or a memory device 120 may store one or more instructions in memory as firmware, and the controller may execute those one or more instructions. Additionally, or alternatively, the controller may receive one or more instructions from the host system 105 and/or from the memory system controller 115, and may execute those one or more instructions. In some implementations, a non-transitory computer-readable medium (e.g., volatile memory and/or non-volatile memory) may store a set of instructions (e.g., one or more instructions or code) for execution by the controller. The controller may execute the set of instructions to perform one or more operations or methods described herein. In some implementations, execution of the set of instructions, by the controller, causes the controller, the memory system 110, and/or a memory device 120 to perform one or more operations or methods described herein. In some implementations, hardwired circuitry is used instead of or in combination with the one or more instructions to perform one or more operations or methods described herein. Additionally, or alternatively, the controller may be configured to perform one or more operations or methods described herein. An instruction is sometimes called a “command.”

For example, the controller (e.g., the memory system controller 115, a local controller 125, or an external controller) may transmit signals to and/or receive signals from memory (e.g., one or more memory arrays 130) based on the one or more instructions, such as to transfer data to (e.g., write or program), to transfer data from (e.g., read), to erase, and/or to refresh all or a portion of the memory (e.g., one or more memory cells, pages, sub-blocks, blocks, or planes of the memory). Additionally, or alternatively, the controller may be configured to control access to the memory and/or to provide a translation layer between the host system 105 and the memory (e.g., for mapping logical addresses to physical addresses of a memory array 130). In some implementations, the controller may translate a host interface command (e.g., a command received from the host system 105) into a memory interface command (e.g., a command for performing an operation on a memory array 130).

In some implementations, one or more systems, devices, apparatuses, components, and/or controllers of FIG. 1 may be configured to receive, from a host system, a write command associated with a first set of data and a first set of parity information; perform, using a shared write/read parity circuit of the memory system and the first set of parity information, a write parity check for the first set of data; receive, from the host system, a read command associated with a second set of data and a second set of parity information; and perform, using the shared write/read parity circuit of the memory system and the second set of parity information, a read parity check for the second set of data.

The number and arrangement of components shown in FIG. 1 are provided as an example. In practice, there may be additional components, fewer components, different components, or differently arranged components than those shown in FIG. 1. Furthermore, two or more components shown in FIG. 1 may be implemented within a single component, or a single component shown in FIG. 1 may be implemented as multiple, distributed components. Additionally, or alternatively, a set of components (e.g., one or more components) shown in FIG. 1 may perform one or more operations described as being performed by another set of components shown in FIG. 1.

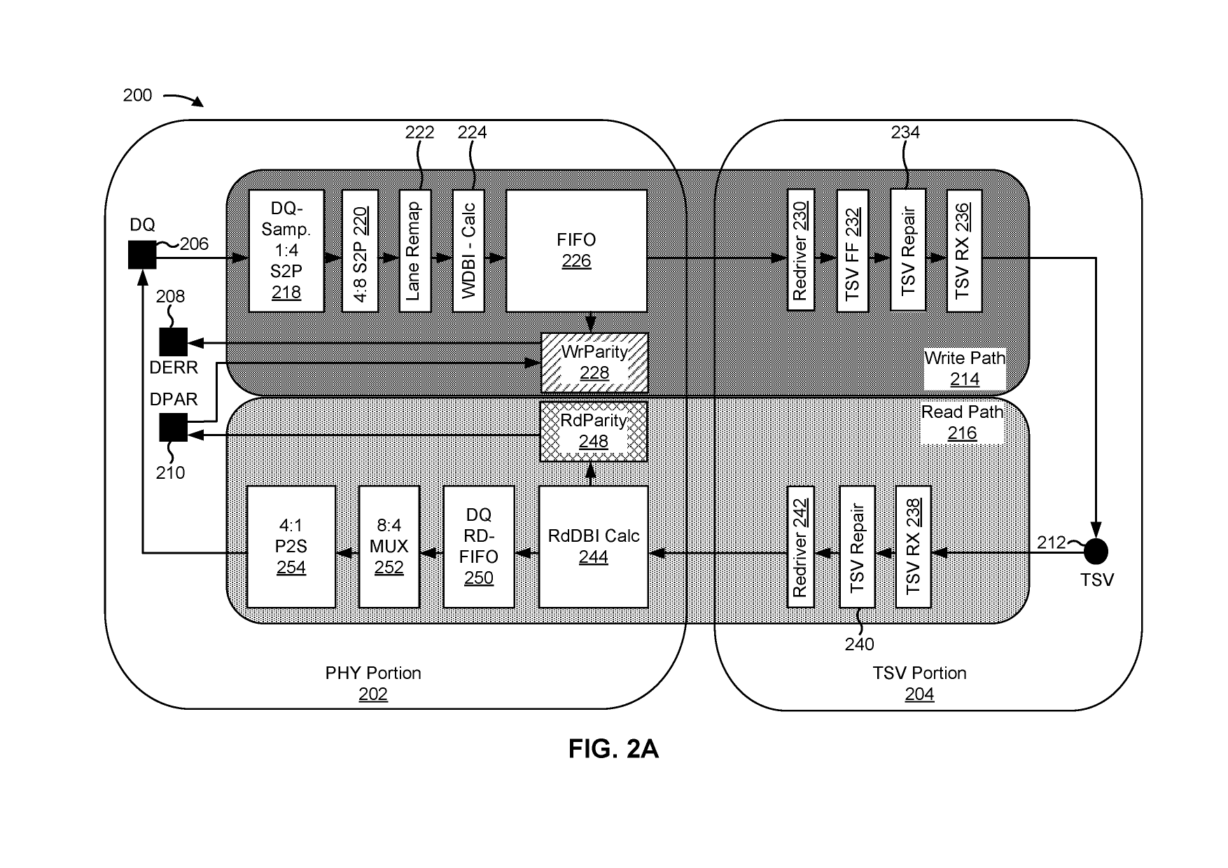

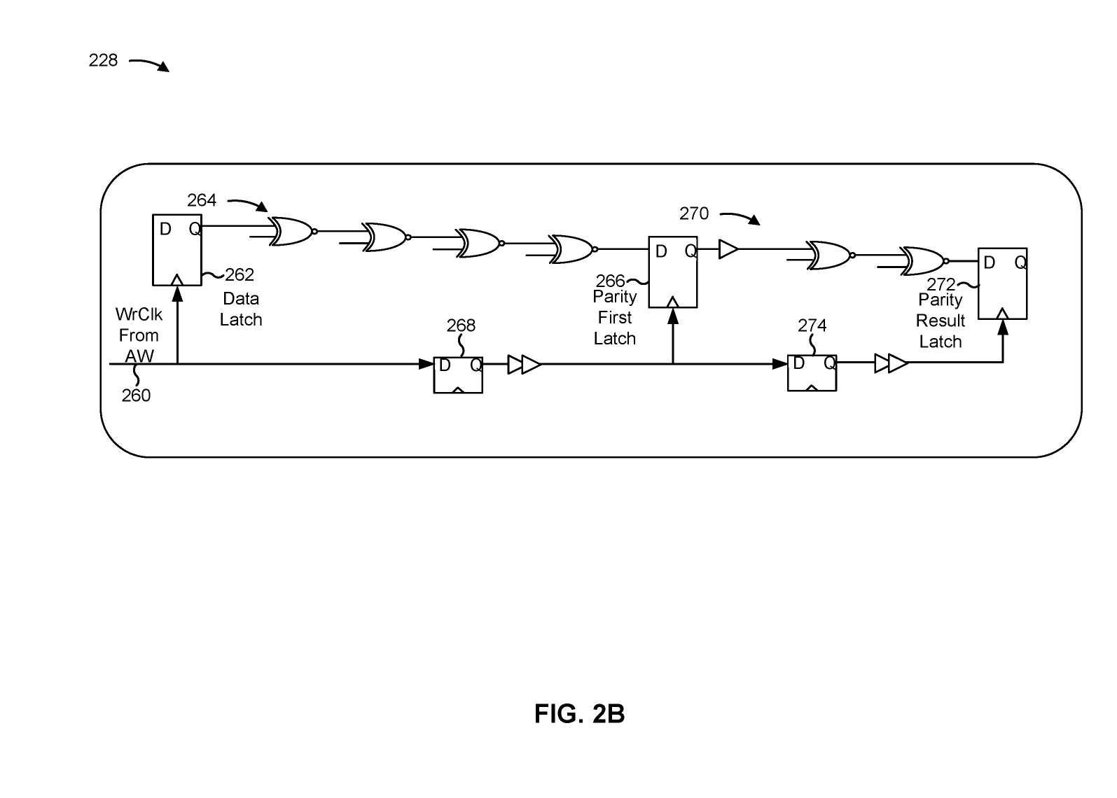

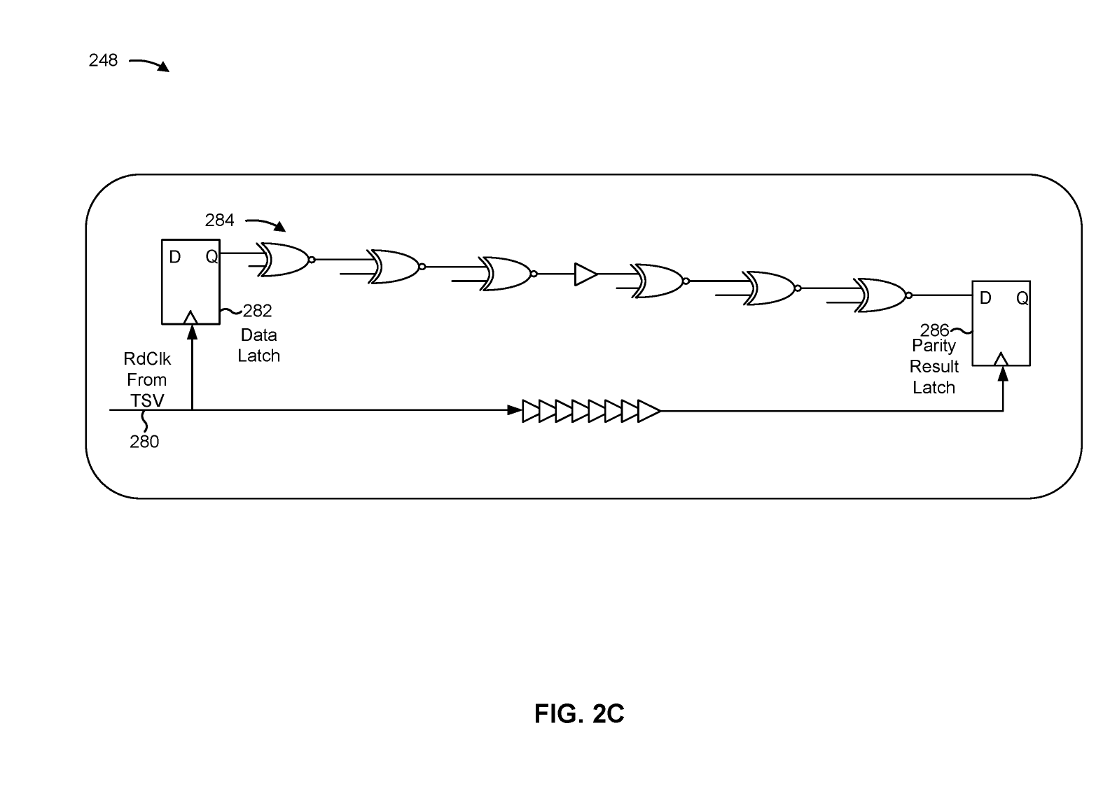

FIGS. 2A-2C are diagrams of examples associated with an HBM system 200 including separate write and read parity circuits. In some examples, the HBM system 200 may use data parity for write and read data, such as to ensure that data is not corrupted during a transmission between a host system (e.g., host system 105) and the HBM system 200, among other examples. In such examples, the HBM system 200 may perform a write parity check and a read parity check using a write parity circuit and/or calculation component and a read parity circuit and/or calculation component, respectively. In some examples, the write parity circuit and the read parity circuit may use data associated with a data queue (DQ), error correction code (ECC), and/or data bus inversion (DBI) in a parity calculation, may determine, based on the parity calculation, whether data to be written to memory (e.g., DRAM) includes one or more bit errors, or may provide parity information to a requesting device (e.g., the host system) such that the requesting device can determine whether data read from the memory includes one or more bit errors .

As shown in FIG. 2A, in some examples the HBM system 200 may be associated with a physical layer (PHY) portion 202 and a TSV portion 204. The HBM system 200 may be generally capable of routing data from a host system (e.g., host system 105) to memory (e.g., a 3D DRAM stack), or from the memory to the host system, via one or more paths or circuits within the HBM system 200. For example, the HBM system 200 may be associated with one or pads used to receive data from, or transmit data to, the host system, such as a DQ pad 206, a data error (DERR) pad 208, and a data parity (DPAR) pad 210. The DQ pad 206 may be associated with one or more physical interface pads where data signals are transmitted and received between the HBM system 200 and the host system. The DERR pad 208 may be used to indicate, to the host system, data errors detected in the HBM system 200. The DPAR pad 210 may be used to transmit or receive parity information for data integrity checks (e.g., write or read parity checks, which are described in more detail below). The HBM system 200 may further include a TSV 212. The TSV 212 may include one or more vertical interconnects used to connect different layers of the HBM stack, allowing for high-density and high-bandwidth communication.

In some implementations, the HBM system 200 may be capable of routing write data from the DQ pad 206 to the TSV 212 (via one or more data processing components) using a write path 214 of the HBM system 200, such as in response to receiving a write command from the host system. Moreover, the HBM system 200 may be capable of routing read data from the TSV 212 to the DQ pad 206 (via one or more data processing components) using a read path 216, such as in response to receiving a read command from the host system.

More particularly, in the PHY portion 202 of the write path 214, write data received from the host system via the DQ pad 206 may be fed to a DQ sampling component 218, which may be a component that samples data from the DQ pads 206 and converts the data from serial to parallel (S2P) format, such as in a 1-to-4 ratio, among other examples. Moreover, the write data may be fed from the DQ sampling component 218 to a S2P component 220, which may be a component that further converts the data, such as from a 4-bit parallel format to an 8-bit parallel format. The write data may be fed from the S2P component 220 to a lane remapping component 222, which may be a component that uses lane remapping to rearrange data lanes to match a required configuration or to optimize signal integrity. The write data may be fed from the lane remapping component 222 to a write DBI (WDBI) calculation component 224, which may be a component that calculates the WDBI to reduce power consumption and improve signal integrity by inverting the data bus, when necessary. Moreover, the write data may be fed from the WDBI calculation component 224 to a first-in first-out (FIFO) component 226, which may include one or more buffers that are used to temporarily store data to manage timing differences between different parts of the system.

The write data may be fed from the FIFO component 226 to a write parity (WrParity) calculation component 228, which may be a component used to calculate parity bits for the write data and compare the parity bits to parity information provided by the host system, such as to ensure data integrity. Parity bits are additional bits added to the data to help detect errors during data transmission. In such examples, the write parity calculation component 228 may receive the write data from the memory controller (e.g., via the FIFO component 226), which may be in parallel format (e.g., 8-bit or 16-bit words, among other examples). The write parity calculation component 228 may calculate the parity bit for each word of data, such as by using an even parity scheme (e.g., a scheme in which a parity bit is set such that the total number of 1s in the data word, including the parity bit, is even) or an odd parity scheme (e.g., a scheme in which the parity bit is set such that the total number of 1s in the data word, including the parity bit, is odd), among other examples. In some examples, the write parity calculation component 228 may compare the calculated parity information with parity information received from the host system. For example, write parity calculation component 228 may receive an indication of the parity information from the host system via the DPAR pad 210, and may compare that parity information to the internally generated parity information. If the parity information is not the same, which may be indicative of an error in the data to be written to the memory, the write parity calculation component may indicate an error via the DERR pad 208. More particularly, if the parity check fails (e.g., the calculated parity bit does not match the received parity bit), an error signal may be generated and sent through the DERR pad 208. Additional details of the write parity calculation component 228 are described in more detail below in connection with FIG. 2B.

In the TSV portion 204 of the write path 214, write data from the FIFO component 226 may be fed to one or more redriver stages 230, which may be used to amplify and clean up signals to ensure they can travel longer distances without degradation. Moreover, write data from the redriver stages 230 may be fed to a TSV flip-flop (FF) 232, which may be a flip-flop circuit used in conjunction with the TSV 212 to store and transfer data across different layers of the HBM stack. The write data from the TSV flip-flop 232 may be fed to a TSV repair component 234, which may be a component that is used to repair faulty TSVs or to maintain the integrity of the data paths. Moreover, the write data from the TSV repair component 234 may be fed to a TSV receiver (RX) 236, which may be a receiver component for the TSV 212 that is responsible for receiving data signals transmitted through the TSV 212. In that regard, write data may be fed from the TSV receiver 236 to the TSV 212, such as for a purpose of storing the write data in the memory (e.g., 3D DRAM stack).

In the TSV portion 204 of the read path 216, read data to be read from memory (e.g., in response to receiving a read command from the host system) may be fed from the TSV 212 to a TSV receiver 238, which may be substantially similar to the TSV receiver 236. Moreover, read data from the TSV receiver 238 may be fed to a TSV repair component 240, which may be substantially similar to the TSV repair component 234. Additionally, or alternatively, read data from the TSV repair component 240 may be fed to one or more redriver stages 242, which may be substantially similar to the one or more redriver stages 230.

In the PHY portion 202 of the read path 216, read data from the one or more redriver stages 242 may be fed to a read DBI (RdDBI) calculation component 244. The RdDBI calculation component 244 may be similar to the WDBI calculation component 224 in that the RdDBI calculation component 244 may be a component that calculates the RdDBI to reduce power consumption and improve signal integrity by inverting the data bus, when necessary. Moreover, read data from the RdDBI calculation component 244 may be fed to a read parity calculation component 248.

The read parity calculation component 248 may be similar to the write parity calculation component 228, in that the read parity calculation component 248 performs parity checks for read data (e.g., data to be returned to a host system in response to a read command received from the host system, among other examples). More particularly, when a read command is issued to the HBM system, the read parity calculation component 248 may be responsible for generating parity bits for the data being read, such as parity bits in connection with an even or odd parity scheme, among other examples. In some examples, the DPAR pad 210 may be used to output the parity bits (e.g., to the host system) generated by the read parity calculation component 248. More particularly, after the parity bits are calculated by the read parity calculation component 248, the parity bits may be sent to the DPAR pad 210, among other examples. These parity bits may then be used by another component (e.g., the host system) to check for errors. More particularly, when the read data reaches the host system (e.g., via the DQ pad 206), the parity bits may be used by the host system to check for errors in the transmitted data. That is, the host system may recalculate the parity based on the received data and may compare the calculated parity bits with the received parity bits from the DPAR pad 210. If there is a mismatch, the host system may determine that an error has occurred during the data transfer. Additional details of the read parity calculation component 248 are described in more detail below in connection with FIG. 2C.

The read data may also be fed from the RdDBI calculation component 244 to a DQ read FIFO component 250, which may be a buffer used to temporarily store read data to manage timing differences between different parts of the system. Additionally, or alternatively, the read data may be fed from the DQ read FIFO component 250 to a multiplexer (MUX) 252, which may be used to select and combine data, such as from an 8-bit parallel format to a 4-bit parallel format. The read data may be fed from the multiplexer 252 to a parallel-to-serial (P2S) converter 254, which may be a component that converts data from a parallel format (e.g., a 4-bit parallel format) to a serial format. Finally, the read data may be fed from the P2S converter 254 to the DQ pads 206, such as for transmission to the host system, among other examples.

FIG. 2B shows various components of circuity associated with the write parity calculation component 228. As described above, the write parity calculation component 228 may be responsible for generating and managing parity information during write operations to ensure data integrity. The write parity calculation component 228 may calculate write parity from write data (e.g., DQ bits, such as 32 DQ bits), ECC data (e.g., ECC bits, such as two ECC bits), and/or DBI data (e.g., DBI bits, such as four DBI bits), among other information. For example, the ECC bits, which are generated based on the data being written or read, may be included in the parity calculation to enhance error detection capabilities. Additionally, or alternatively, DBI is a technique used to reduce power consumption and improve signal integrity by inverting the data bus when necessary. The DBI bits may be included in the parity calculation to ensure that any errors introduced by the DBI process are detected. By integrating ECC and DBI data into the parity calculations, the memory system can achieve higher data reliability and integrity. In some implementations, the write parity calculation includes four series of exclusive OR (XOR) circuits, one flip-flop circuit, and two series of XOR circuits.

In that regard, as indicated by reference number 260, the write parity calculation component 228 may receive a write clock (WrClk) signal, such as from an address write (AW) component of the HBM system 200 (not shown). The WrClk signal is a signal that synchronizes the write operations in the HBM system 200. In some implementations, the WrClk signal is derived from the AW phase to ensure all components in the write parity calculation component 228 operate in synchronization with the write operations. Additionally, or alternatively, the WrClk signal provides the timing reference for latching data and generating parity bits. The WrClk signal may be fed to a data latch 262, which temporarily holds the write data that is to be written to the memory cells. Put another way, when a write command is issued, the data to be written is captured and held by the data latch 262 to ensure that the data is stable and available for parity calculation. In some examples, the data latch 262 is triggered by the WrClk from the AW component, ensuring that the data is latched at the correct time in the write cycle.

As indicated by reference number 264, the write parity calculation includes, in this example, four series of XOR operations. Following the four series of XOR operations, the parity data is stored at a parity first latch 266. The parity first latch 266 may be used to capture and hold the initial parity calculation result based on the data in the data latch 262. Put another way, the parity calculation logic may generate an initial parity bit (or bits) based on the data, and the initial parity result may be captured by the parity first latch. As shown in FIG. 2B, the parity first latch 266 may also be triggered by the WrClk signal, ensuring that the initial parity result is latched at the correct time. In some examples, the parity first latch 266 may be associated with a flip-flop circuit used to improve a stability of margins during the write parity calculation operation. In some examples, the WrClk signal may also pass through a flip-flop circuit 268 prior to triggering the parity first latch 266.

As indicated by reference number 270, after the parity first latch 266, the write parity calculation includes, in this example, two additional series of XOR operations. Following the two series of XOR operations, the parity data is stored at a parity result latch 272. The Parity result latch 272 may hold the final parity bits that are used to perform the write parity check (e.g., that are compared to parity bits received from the host system). As shown in FIG. 2B, the parity result latch 272 may be triggered by the WrClk signal, ensuring that the final parity bits are latched at the correct time and are synchronized with the data being written. Moreover, in some examples, the WrClk signal may also pass through a flip-flop circuit 274 prior to triggering the parity result latch 272. Additionally, or alternatively, in some examples a clock for the parity result latch 272 is asynchronously delayed from a shift register signal.

FIG. 2C shows various components of circuity associated with the read parity calculation component 248. As described above, the read parity calculation component 248 may be responsible for generating and managing parity information during read operations to ensure data integrity. The read parity calculation component 248 may calculate read parity from read data (e.g., DQ bits, such as 32 DQ bits), ECC data (e.g., ECC bits, such as two ECC bits), and/or DBI data (e.g., DBI bits, such as four DBI bits), among other information. In some implementations, the read parity calculation includes six series of XOR circuits, without a flip-flop circuit in the middle.

In that regard, as indicated by reference number 280, the read parity calculation component 248 may receive a read clock (RdClk) signal from the TSV 212. The RdClk signal is a signal used to synchronize the read operations in the HBM system 200, such as by ensuring that data is read at the correct times and in the correct sequence. The RdClk signal may trigger a data latch 282, which may be used to temporarily hold the data being read from the memory cells. The data latch 282 may ensure that the data remains stable and available for subsequent processing, such as parity checking, until the next read operation.

As indicated by reference number 284, the read parity calculation includes, in this example, six series of XOR operations. Unlike the write parity calculation described above, in this example there may be no flip-flop circuitry in the series of XOR operations (e.g., the read parity calculation circuitry may not include a circuit corresponding to the parity first latch 266 described above in connection with FIG. 2B). Following the six series of XOR operations, the parity data is stored at a parity result latch 286. Similar to the parity result latch 272 described above in connection with FIG. 2B, the parity result latch 286 may be used to hold the result of the parity check operation. As shown in FIG. 2C, the parity result latch 286 may be controlled by the RdClk signal. In this regard, when the clock signal is active, the parity result latch 286 may capture the result of the parity check, and, when the clock signal is inactive, the parity result latch 286 may hold the parity result stable. In some examples, the clock for the parity result latch 286 may be delayed from the data latch 282.

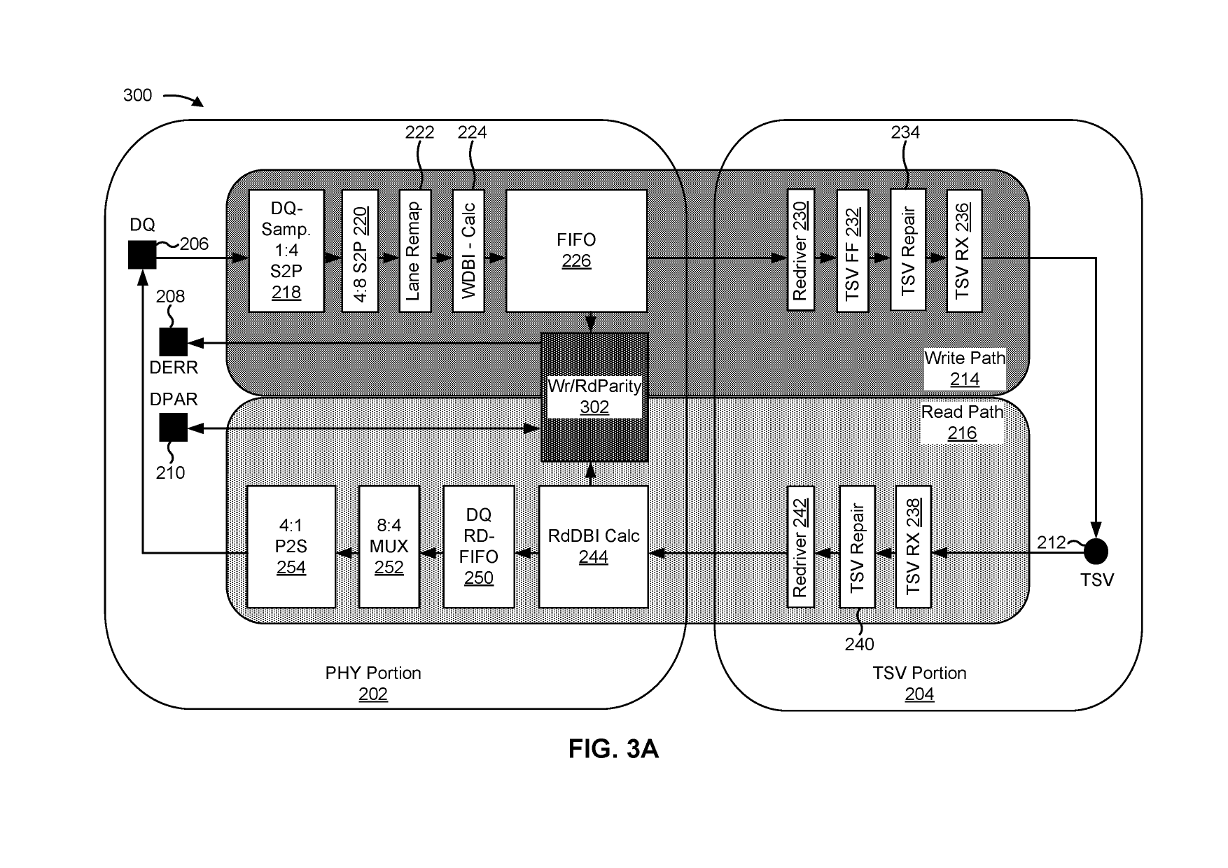

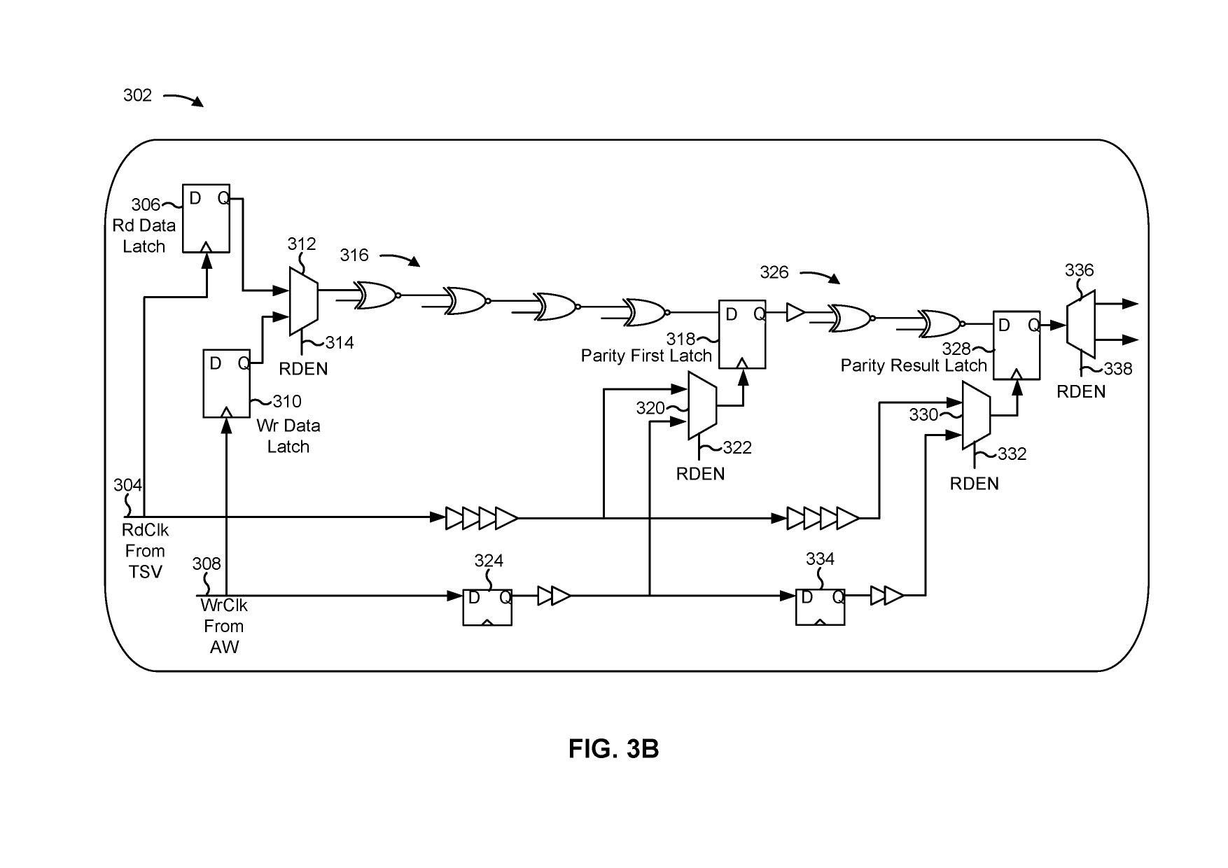

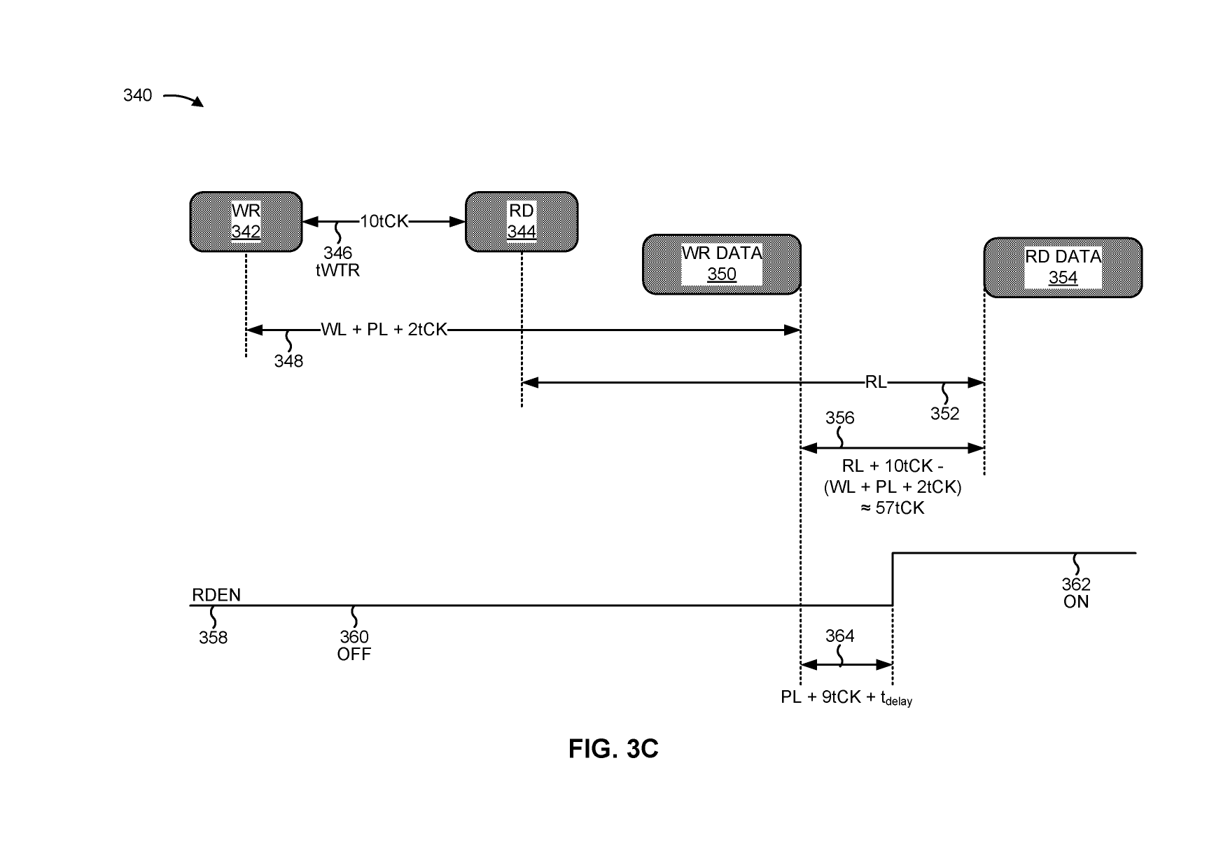

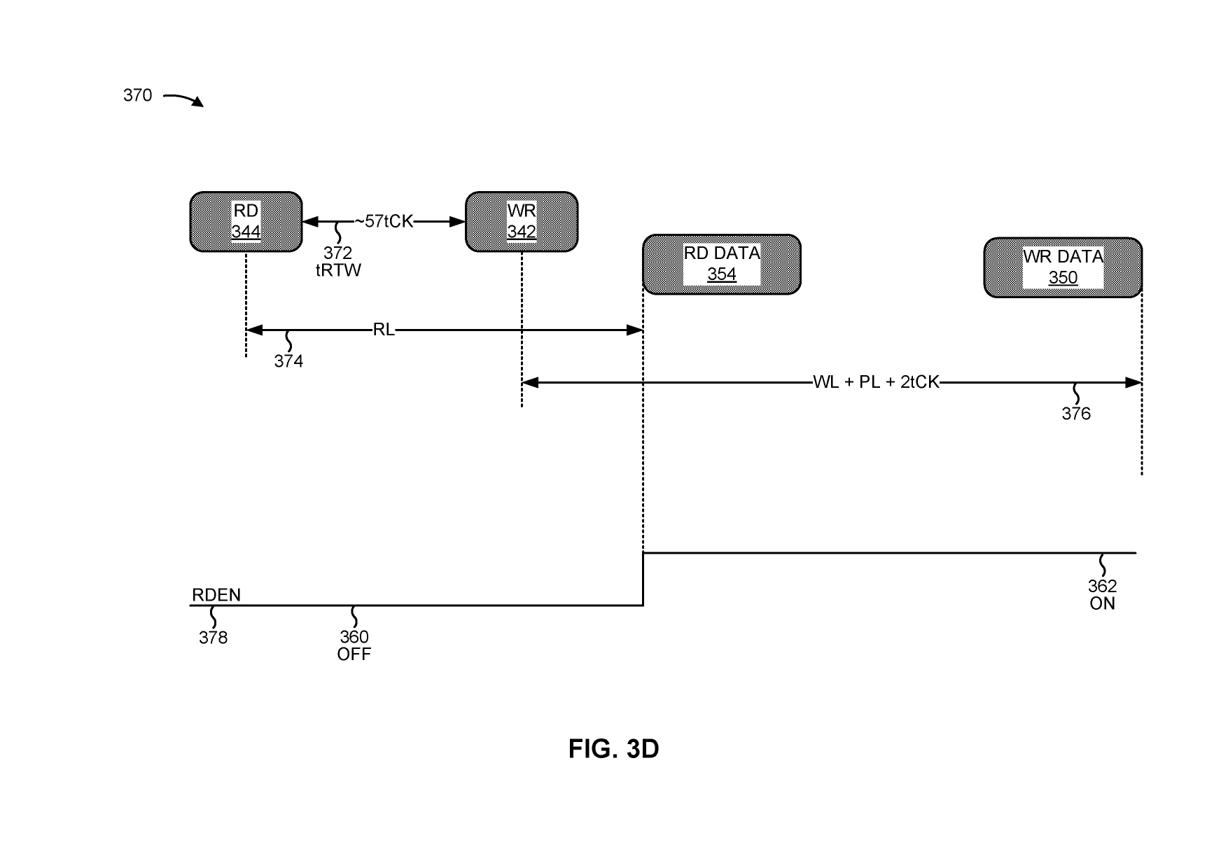

In this regard, the two distinct circuitries of the write parity calculation component 228 and the read parity calculation component 248 may collectively occupy a large area in the HBM system 200 and/or may be associated with high power consumption in the HBM system 200. Accordingly, in some implementations described herein, a write parity calculation component and a read parity calculation component may share circuity in a memory system, resulting in a reduced area in the memory system for hosting the write and read parity calculation circuitry as well as reduced power consumption for the write and read parity calculation circuitry. Aspects of a shared write/read parity circuit are described in more detail below in connection with FIGS. 3A-3D.

As indicated above, FIGS. 2A-2C are provided as examples. Other examples may differ from what is described with regard to FIGS. 2A-2C.

FIGS. 3A-3D are diagrams associated with an HBM system 300 including a shared write/read parity circuit 302. The HBM system 300 may include many of the same components described above in connection with the HBM system 200, which are shown using like reference numbers in FIG. 3A and which are not described again in detail for ease of description. Moreover, and in a similar manner as described above in connection with the HBM system 200, the HBM system 300 may use data parity for write and read data, such as using data associated with a DQ, an ECC, and/or a DBI in a parity calculation, and by determining, based on the parity calculation, whether data to be written to memory (e.g., DRAM) includes one or more bit errors or for enabling another device (e.g., a host system) to determine if data being read from memory has one or more bit errors.

However, in this implementation, and unlike the HBM system 200 (which includes the separate write parity calculation component 228 and read parity calculation component 248), the HBM system 300 may perform a write parity check and a read parity check using a shared write/read parity circuit 302. In that regard, the shared write/read parity circuit 302 may form part of both the write path 214 and the read path 216 as shown, and the HBM system 300 may be configured to selectively route signals to the shared write/read parity circuit 302 based on whether data is being written to the memory or read from the memory. For example, the HBM system 300 may assert a read enable (RDEN) signal to control an operation of the shared write/read parity circuit 302, such as by asserting the RDEN signal when the shared write/read parity circuit 302 is to be used for the read parity check and to omit assertion of the RDEN signal when the shared write/read parity circuit 302 is to be used for the write parity check.

More particularly, to perform the write parity check, the HBM system 300 may omit assertion of the RDEN signal at one or more multiplexers associated with the shared write/read parity circuit 302, and, to perform the read parity check, the HBM system 300 may assert the RDEN signal at the one or more multiplexers associated with the shared write/read parity circuit 302 (which is described in more detail below in connection with FIG. 3B). In that regard, the shared write/read parity circuit 302 may be configured to selectively receive signals from one of the FIFO component 226 or the RdDBI calculation component based on whether the RDEN signal is asserted. Moreover, the shared write/read parity circuit 302 may be configured to selectively perform one of receive parity information from the host system using the DPAR pad 210 and assert any errors associated with a write parity check using the DERR pad 208, or else transmit to the host system parity information associated with a read parity check using the DPAR pad 210, based on whether the RDEN signal is asserted.

The introduction of the RDEN signal may ensure that write and read operations are adequately segregated to prevent conflicts. The RDEN signal may be asserted to control the operation of the shared write/read parity circuit 302, effectively toggling between write and read modes. This signal ensures that write data and read data do not overlap, thus maintaining data integrity and synchronization. For instance, when a write command is completed, the RDEN signal is asserted after a specific time period, ensuring that the transition from write to read operations occurs seamlessly. Similarly, when a read command is received prior to a write command, the RDEN signal is asserted to prioritize the read operation, ensuring timely data access with minimal latency.

Accordingly, when the HBM system 300 is executing a write command, the HBM system 300 may perform, using the shared write/read parity circuit 302, a write parity check for the first set of data (e.g., compare calculated parity information to parity information provided by the host system). Similarly, when the HBM system 300 is executing a read command, the HBM system 300 may perform, using the shared write/read parity circuit 302, a read parity check (e.g., calculate parity information and transmit the parity information to the host system to enable the host system to perform a parity check associated with the read data). In this way, the shared write/read parity circuit 302 may eliminate redundant or duplicate circuitry associated with the distinct write parity calculation component 228 and the read parity calculation component 248 described above, thus reducing an area in the HBM system 300 needed for parity calculation circuitry and/or reducing power demands of the HBM system 300 (as compared to the HBM system 200). For example, as described in more detail below in connection with FIG. 3B, in some implementations a certain number of multiplexers may be added to the shared write/read parity circuit 302 (as compared to the collective circuitry forming the write parity calculation component 228 and the read parity calculation component 248), but numerous XOR circuits, buffers, and/or flip-flop circuits may be eliminated from the shared write/read parity circuit 302 (as compared to the collective circuitry forming the write parity calculation component 228 and the read parity calculation component 248), resulting in reduced area and power demands.

FIG. 3B shows the shared write/read parity circuit 302 in more detail. As shown in FIG. 3B, an as indicated by reference number 304, the shared write/read parity circuit 302 may receive a RdClk signal from the TSV 212, which may be used to control the operation of a read data latch 306 (which may be substantially similar to the data latch 282 described above in connection with the read parity calculation component 248). Moreover, as indicated by reference number 308, the shared write/read parity circuit 302 may receive a WrClk signal from the AW component, which may be used to control the operation of a write data latch 310 (which may be substantially similar to the data latch 262 described above in connection with the write parity calculation component 228).

Signals from the read data latch 306 and the write data latch 310 may be fed to a multiplexer 312, which may be controlled by the RDEN signal, as indicated by reference number 314. In that way, the HBM system 300 may selectively route read data or write data through the shared write/read parity circuit 302 based on whether the RDEN has been asserted. As used herein, “selectively” performing a first operation or a second operation means to perform either the first operation or the second operation. For example, selectively performing a first operation or a second operation based on whether a condition is satisfied means that the first operation is performed if the condition is satisfied and that the second operation is performed if the condition is not satisfied (or vice versa). Thus, selectively performing a first operation or a second operation may include determining whether to perform either the first operation or the second operation and then performing either the first operation or the second operation based on that determination.

In the context of the shared write/read parity circuit 302 shown in FIG. 3B, the HBM system 200 may selectively feed signals through the circuitry based on whether the RDEN signal is asserted at the various components. More particularly, when the RDEN signal is asserted at the multiplexer 312, a signal from the read data latch 306 may be provided to four series of XOR circuits, as indicated by reference number 316 (which may be substantially similar the four series of XOR circuits described above in connection with reference number 264 or the first four of the six series of XOR circuits described above in connection with reference number 284). On the other hand, when the RDEN signal is not asserted at the multiplexer 312, a signal from the write data latch 310 may be provided to the four series of XOR circuits indicated by reference number 316.

Following the four series of XOR operations, the parity data is stored at a parity first latch 318 (which may be substantially similar to the parity first latch 266). The parity first latch 318 may be used to capture and hold the initial parity calculation result based on the data in the read data latch 306 or the write data latch 310. Put another way, the parity calculation logic may generate an initial parity bit (or bits) based on the data that is selectively fed to the four series of XOR circuits, and the initial parity result may be captured by the parity first latch 318. In some implementations, the parity first latch 318 may be associated with a flip-flop circuit used to improve a stability of margins during the read or write parity calculation operations. As shown in FIG. 3B, the parity first latch 318 may be triggered by one of RdClk signal or the WrClk signal, ensuring that the initial parity result is latched at the correct time. More particularly, the parity first latch 318 may be associated with a multiplexer 320 that is controlled by the RDEN signal, as indicated by reference number 322. When the RDEN signal is asserted at the multiplexer 320, the RdClk signal may be fed to the parity first latch 318. On the other hand, when the RDEN signal is not asserted at the multiplexer 320, the WrClk signal may be fed to the parity first latch 318. In some examples, the WrClk signal may also pass through a flip-flop circuit 324 prior to the multiplexer 320 and the parity first latch 318.

As indicated by reference number 326, after the parity first latch 318, the read or write parity calculation includes, in this example, two additional series of XOR operations (which may be substantially similar to the two series of XOR operations described above in connection with reference number 270 or the final two of the six XOR operations described above in connection with reference number 284). Following the two series of XOR operations, the parity data is stored at a parity result latch 328. The parity result latch 328 (which may be substantially similar to the parity result latch 272 and/or the parity result latch 286) may hold the final parity bits that will transmitted to the host system or used to perform a parity check, among other examples. As shown in FIG. 3B, the parity result latch 328 may be selectively triggered by one of RdClk signal or the WrClk signal, ensuring that the initial parity result is latched at the correct time. More particularly, the parity result latch 328 may be associated with a multiplexer 330 that is controlled by the RDEN signal, as indicated by reference number 332. When the RDEN signal is asserted at the multiplexer 330, the RdClk signal may be fed to the parity result latch 328. On the other hand, when the RDEN signal is not asserted at the multiplexer 330, the WrClk signal may be fed to the parity result latch 328. In some examples, the WrClk signal may also pass through a flip-flop circuit 334 prior to the multiplexer 330 and the parity result latch 328.

As further shown in FIG. 3B, data from the parity result latch 328 may selectively be fed to other circuits in the HBM system using another multiplexer 336 that is associated with the RDEN signal, as indicated by reference number 338. For example, when the RDEN signal is asserted at the multiplexer 336, the data may be fed to circuitry associated with the read parity check and/or the read command. On the other hand, when the RDEN signal is not asserted at the multiplexer 336, the data may be fed to circuitry associated with the write parity check and/or the write command.

FIG. 3C shows an example timing diagram 340 associated with assertion of the RDEN signal. In the timing diagram 340, a write command 342 is received prior to a read command 344. As indicated by reference number 346, in some implementations the HBM system 300 may be associated with a write to read delay (sometimes referred to as tWTR), which is a delay required between the completion of a write operation and the initiation of a subsequent read operation. This timing parameter may ensure that the memory cells have sufficient time to stabilize after a write before a read operation can be performed. For example, in some implementations, the tWTR may be equal to ten clock cycles (sometimes referred to as tCK).

In such implementations, and as indicated by reference number 348, the HBM system 300 may be associated with a certain delay from when the write command 342 is received form the host system and when the associated write data 350 is written to memory. For example, the time period indicated by reference number 348 may be equal to a write latency (WL) associated with the HBM system 300 (e.g., a delay between the initiation of the write command 342 and the moment when the data is actually written to the memory cells), plus a parity latency (PL) associated with the HBM system 300 (e.g., a delay associated with the generation and checking of parity bits for error detection and correction, such as via the shared write/read parity circuit 302), and any additionally configured delay (such as 2tCK in the example shown in FIG. 3B).

Moreover, and as indicated by reference number 352, the HBM system 300 may be associated with a certain delay from when the read command 344 is received from the host system and when the read data 354 is ready for output. For example, the time period indicated by reference number 352 may be equal to a read latency (RL) associated with the HBM system (e.g., a delay between the initiation of the read command 344 and the moment when the requested read data 354 is available). In that regard, and as indicated by 356, there may be a period of time between when the write data 350 is fully written to memory and when the read data 354 is available for output that is equal to the RL plus the tWTR (e.g., 10 tCK, in some implementations) and minus the sum of the WL, the PL, and 2tCK (which, in some implementations, may be approximately 57tCK).

In some implementations, and as indicated by reference number 358, the RDEN signal may be asserted during the time period indicated by reference number 356, such as for a purpose of enabling the shared write/read parity circuit 302 to selectively perform the write parity check prior to the assertion of the RDEN signal (e.g., in connection with the write command 342) and to selectively perform the read parity check after assertion of the RDEN signal (e.g., in connection with the read command 344). More particularly, as shown in FIG. 3C, the RDEN signal may be toggled between OFF (as indicated by reference number 360) and ON (as indicated by reference number 362) during the time period indicated by reference number 356. Put another way, in implementations in which the write command 342 is received by the HBM system 300 prior to the read command 344, the HBM system 300 may write the write data 350 to memory (e.g., based on the write data 350 passing the write parity check), and the HBM system may assert the RDEN signal a time period after writing the write data 350 to the memory. In some implementations, the time period after writing the write data 350 to the memory when the RDEN signal is asserted may be equal to the PL plus 9tCK, and, optionally, a certain time delay (shown as t_{delay} in FIG. 3C), as indicated by reference number 364.

FIG. 3D shows another example timing diagram 370 associated with assertion of the RDEN signal. In the timing diagram 370, the read command 344 is received prior to the write command 342. As indicated by reference number 372, in some implementations the HBM system 300 may be associated with a read to write delay (sometimes referred to as tRTW), which is a delay required between the completion of a read operation and the initiation of a subsequent write operation. This timing parameter ensures that the memory controller has enough time to switch from reading to writing mode. In some implementations, the tRTW may be equal to approximately 57tCK.

In a similar manner as described above in connection with reference number 352, the HBM system 300 may be associated an RL, as indicated by reference number 374. Moreover, in a similar manner as described above in connection with reference number 348, the HBM system 300 may be associated with a certain delay from when the write command 342 is received form the host system and when the associated write data 350 is written to memory (which may be equal to the WL plus the PL plus 2tCK, as indicated by reference number 376).

In this implementation, and as indicated by reference number 378, the RDEN signal may be asserted prior to reading the read data 354. For example, in this implementation the RDEN signal may be asserted a time period after receiving the read command 344 equal to the RL, as shown in FIG. 3D. Put another way, in some implementations, such as implementations in which the read command 344 is received by the HBM system 300 prior to the write command 342, the HBM system 300 may be configured to assert the RDEN signal based on receiving the read command 344 and prior to reading the read data 354 from memory, such as by asserting the RDEN signal a time period that is less than or equal to the RL after receiving the read command 344.

As indicated above, FIGS. 3A-3D are provided as examples. Other examples may differ from what is described with regard to FIGS. 3A-3D. The number and arrangement of devices shown in FIGS. 3A-3D are provided as an example. In practice, there may be additional devices, fewer devices, different devices, or differently arranged devices than those shown in FIGS. 3A-3D. Furthermore, two or more devices shown in FIGS. 3A-3D may be implemented within a single device, or a single device shown in FIGS. 3A-3D may be implemented as multiple, distributed devices. Additionally, or alternatively, a set of devices (e.g., one or more devices) shown in FIGS. 3A-3D may perform one or more functions described as being performed by another set of devices shown in FIGS. 3A-3D.

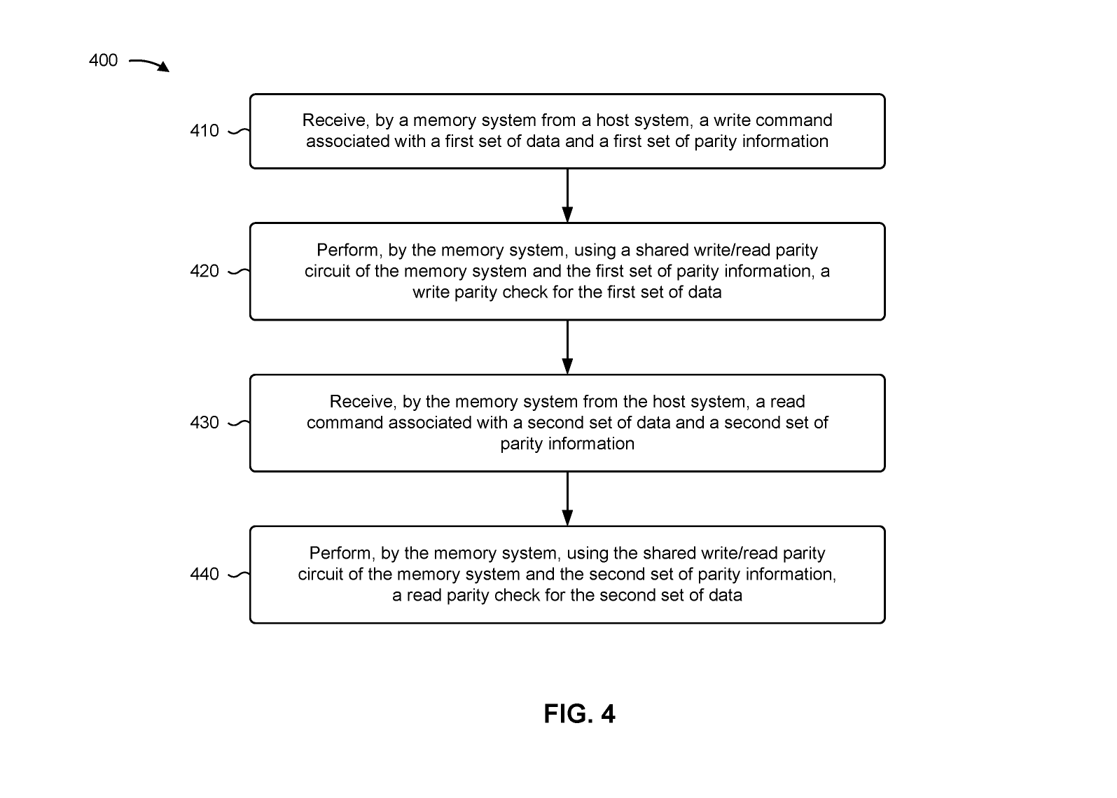

FIG. 4 is a flowchart of an example method 400 associated with memory systems including a shared write/read parity circuit. In some implementations, a memory system (e.g., the HBM system 300) may perform or may be configured to perform the method 400. In some implementations, another device or a group of devices separate from or including the memory system (e.g., memory system 110) may perform or may be configured to perform the method 400. Additionally, or alternatively, one or more components of the memory system (e.g., memory system controller 115, local controller 125, memory array 130, shared write/read parity circuit 302, and/or any of the components described above in connection with the write path 214 and the read path 216 of the HBM system 300) may perform or may be configured to perform the method 400. Thus, means for performing the method 400 may include the memory system and/or one or more components of the memory system. Additionally, or alternatively, a non-transitory computer-readable medium may store one or more instructions that, when executed by the memory system, cause the memory system to perform the method 400.

As shown in FIG. 4, the method 400 may include receiving a write command associated with a first set of data and a first set of parity information (block 410). For example, the HBM system 300 may receive the write command 342 described above in connection with FIGS. 3C and 3D, among other examples.

As further shown in FIG. 4, the method 400 may include performing, using a shared write/read parity circuit of the memory system and the first set of parity information, a write parity check for the first set of data (block 420). For example, the HBM system 300 may perform a write parity check using the shared write/read parity circuit 302, such as by omitting assertion of the RDEN signal and thereby routing the write data and/or WrClk signals through the shared write/read parity circuit 302, among other examples.

As further shown in FIG. 4, the method 400 may include receiving a read command associated with a second set of data and a second set of parity information (block 430). For example, the HBM system 300 may receive the read command 344 described above in connection with FIGS. 3C and 3D, among other examples.

As further shown in FIG. 4, the method 400 may include performing using the shared write/read parity circuit of the memory system and the second set of parity information, a read parity check for the second set of data (block 440). For example, the HBM system 300 may perform a read parity check using the shared write/read parity circuit 302, such as by asserting the RDEN signal and thereby routing the read data and/or RdClk signals through the shared write/read parity circuit 302, among other examples.

The method 400 may include additional aspects, such as any single aspect or any combination of aspects described below and/or described in connection with one or more other methods or operations described elsewhere herein.

In a first aspect, the method 400 includes asserting a read enable signal to control an operation of the shared write/read parity circuit. For example, the HBM system 300 may assert the RDEN signal described above in connection with shared write/read parity circuit 302, among other examples.

In a second aspect, alone or in combination with the first aspect, performing the write parity check includes performing the write parity check based on an absence of an assertion of the read enable signal at one or more multiplexers associated with the shared write/read parity circuit, and performing the read parity check includes performing the read parity check based on the assertion of the read enable signal at the one or more multiplexers associated with the shared write/read parity circuit. For example, the HBM system 300 may selectively route the write data and/or WrClk signals through the shared write/read parity circuit 302 when the RDEN signal is not asserted at the multiplexers 312, 320, 330, 336, and the HBM system 300 may selectively route the read data and/or RdClk signals through the shared write/read parity circuit 302 when the RDEN signal is asserted at the multiplexers 312, 320, 330, 336, among other examples.

In a third aspect, alone or in combination with one or more of the first and second aspects, the write command is received by the memory system prior to the read command, and the method 400 further includes writing the first set of data and the first set of parity information to one or more memory components associated with the memory system based on the first set of data passing the write parity check, and asserting the read enable signal a time period after writing the first set of data and the first set of parity information to the one or more memory components. For example, as described above in connection with FIG. 3C, the HBM system 300 may assert the RDEN signal the time period indicated by reference number 364 after writing the write data 350 to memory, among other examples.

In a fourth aspect, alone or in combination with one or more of the first through third aspects, the read command is received by the memory system prior to the write command, and the method 400 further includes reading the second set of data and the second set of parity information from one or more memory components associated with the memory system, and asserting the read enable signal based on receiving the read command. For example, as described above in connection with FIG. 3D, the HBM system 300 may assert the RDEN signal a time period that is less than or equal to the RL after receiving the read command 344, among other examples.

In a fifth aspect, alone or in combination with one or more of the first through fourth aspects, the shared write/read parity circuit includes a flip-flop component and an associated multiplexer, and the method 400 further includes selectively routing, by the memory system to the flip-flop component, one of a first data input associated with the write command or a second data input associated with the read command based on whether the read enable signal is asserted at the multiplexer. For example, as described above in connection with FIG. 3B, the shared write/read parity circuit 302 may include the parity first latch 318 to act as a flip-flop circuit, and the HBM system 300 may selectively route, to the parity first latch 318, the RdClk signal or the WrClk signal based on whether the RDEN signal is asserted at the multiplexer 320 associated with the parity first latch 318, among other examples.

In a sixth aspect, alone or in combination with one or more of the first through fifth aspects, the shared write/read parity circuit includes a parity result latch and an associated multiplexer, and the method further comprises selectively routing, by the memory system to the parity result latch, one of a first data input associated with the write command or a second data input associated with the read command based on whether the read enable signal is asserted at the multiplexer. For example, as described above in connection with FIG. 3B, the shared write/read parity circuit 302 may include the parity result latch 328, and the HBM system 300 may selectively route, to the parity result latch 328, the RdClk signal or the WrClk signal based on whether the RDEN signal is asserted at the multiplexer 330 associated with the parity result latch 328, among other examples.

In a seventh aspect, alone or in combination with one or more of the first through sixth aspects, the shared write/read parity circuit is associated with a read data latch and a write data latch, performing the write parity check includes performing the write parity check based on a write clock signal asserted at the write data latch, and performing the read parity check includes performing the read parity check based on a read clock signal asserted at the read data latch. For example, as described above in connection with FIG. 3B, the shared write/read parity circuit 302 may include the read data latch 306 and the write data latch 310, and the shared write/read parity circuit 302 may perform the read parity check when the RdClk signal is asserted at the read data latch 306 and may perform the write parity check when the WrClk signal is asserted at the write data latch 310, among other examples.

In an eighth aspect, alone or in combination with one or more of the first through seventh aspects, the method 400 includes transmitting, by the memory system to the host system and via at least one of a data error pad associated with the memory system or a data parity pad associated with the memory system, one or more results associated with at least one of the write parity check or the read parity check. For example, as described above in connection with FIG. 3A, the HBM system 300 may transmit one or more results associated with write parity check or the read parity check via the DERR pad 208 or the DPAR pad 210, among other examples.

Although FIG. 4 shows example blocks of a method 400, in some implementations, the method 400 may include additional blocks, fewer blocks, different blocks, or differently arranged blocks than those depicted in FIG. 4. Additionally, or alternatively, two or more of the blocks of the method 400 may be performed in parallel. The method 400 is an example of one method that may be performed by one or more devices described herein. These one or more devices may perform or may be configured to perform one or more other methods based on operations described herein.

In some implementations, a memory system includes one or more components configured to: receive, from a host system, a write command associated with a first set of data and a first set of parity information; perform, using a shared write/read parity circuit of the memory system and the first set of parity information, a write parity check for the first set of data; receive, from the host system, a read command associated with a second set of data and a second set of parity information; and perform, using the shared write/read parity circuit of the memory system and the second set of parity information, a read parity check for the second set of data.

In some implementations, a method includes receiving, by a memory system from a host system, a write command associated with a first set of data and a first set of parity information; performing, by the memory system, using a shared write/read parity circuit of the memory system and the first set of parity information, a write parity check for the first set of data; receiving, by the memory system from the host system, a read command associated with a second set of data and a second set of parity information; and performing, by the memory system, using the shared write/read parity circuit of the memory system and the second set of parity information, a read parity check for the second set of data.

In some implementations, an HBM system includes a shared write/read parity circuit; and one or more memory components operatively coupled to the shared write/read parity circuit, wherein the HBM system is configured to: receive, from a host system, a write command associated with a first set of data to be written to the one or more memory components and a first set of parity information associated with the first set of data; perform, using the shared write/read parity circuit and the first set of parity information, a write parity check for the first set of data; receive, from the host system, a read command associated with a second set of data to be read from the one or more memory components and a second set of parity information associated with the second set of data; and perform, using the shared write/read parity circuit and the second set of parity information, a read parity check for the second set of data.

The foregoing disclosure provides illustration and description but is not intended to be exhaustive or to limit the implementations to the precise forms disclosed. Modifications and variations may be made in light of the above disclosure or may be acquired from practice of the implementations described herein.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

When “a component” or “one or more components” (or another element, such as “a controller” or “one or more controllers”) is described or claimed (within a single claim or across multiple claims) as performing multiple operations or being configured to perform multiple operations, this language is intended to broadly cover a variety of architectures and environments. For example, unless explicitly claimed otherwise (e.g., via the use of “first component” and “second component” or other language that differentiates components in the claims), this language is intended to cover a single component performing or being configured to perform all of the operations, a group of components collectively performing or being configured to perform all of the operations, a first component performing or being configured to perform a first operation and a second component performing or being configured to perform a second operation, or any combination of components performing or being configured to perform the operations. For example, when a claim has the form “one or more components configured to: perform X; perform Y; and perform Z,” that claim should be interpreted to mean “one or more components configured to perform X; one or more (possibly different) components configured to perform Y; and one or more (also possibly different) components configured to perform Z.”

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A memory system, comprising:
one or more components configured to:
receive, from a host system, a write command associated with a first set of data and a first set of parity information;
perform, using a shared write/read parity circuit of the memory system and the first set of parity information, a write parity check for the first set of data;
receive, from the host system, a read command associated with a second set of data and a second set of parity information; and
perform, using the shared write/read parity circuit of the memory system and the second set of parity information, a read parity check for the second set of data.

2. The memory system of claim 1, wherein the one or more components are further configured to assert a read enable signal to control an operation of the shared write/read parity circuit.

3. The memory system of claim 2, wherein the one or more components, to perform the write parity check, are configured to perform the write parity check based on an absence of an assertion of the read enable signal at one or more multiplexers associated with the shared write/read parity circuit, and
wherein the one or more components, to perform the read parity check, are configured to perform the read parity check based on the assertion of the read enable signal at the one or more multiplexers associated with the shared write/read parity circuit.

4. The memory system of claim 2, wherein the write command is received by the memory system prior to the read command, and
wherein the one or more components are further configured to:
write the first set of data and the first set of parity information to one or more memory components associated with the memory system based on the first set of data passing the write parity check; and
assert the read enable signal a time period after writing the first set of data and the first set of parity information to the one or more memory components.

5. The memory system of claim 2, wherein the read command is received by the memory system prior to the write command, and
wherein the one or more components are further configured to:
read the second set of data and the second set of parity information from one or more memory components associated with the memory system; and
assert the read enable signal based on receiving the read command.

6. The memory system of claim 2, wherein the shared write/read parity circuit includes a flip-flop component and an associated multiplexer, and
wherein the one or more components are further configured to selectively route, to the flip-flop component, one of a first data input associated with the write command or a second data input associated with the read command based on whether the read enable signal is asserted at the multiplexer.

7. The memory system of claim 2, wherein the shared write/read parity circuit includes a parity result latch and an associated multiplexer, and
wherein the one or more components are further configured to selectively route, to the parity result latch, one of a first data input associated with the write command or a second data input associated with the read command based on whether the read enable signal is asserted at the multiplexer.

8. The memory system of claim 1, wherein the shared write/read parity circuit is associated with a read data latch and a write data latch,
wherein the one or more components, to perform the write parity check, are configured to perform the write parity check based on a write clock signal asserted at the write data latch, and
wherein the one or more components, to perform the read parity check, are configured to perform the read parity check based on a read clock signal asserted at the read data latch.

9. The memory system of claim 1, wherein the one or more components are configured to transmit, to the host system and via at least one of a data error pad associated with the memory system or a data parity pad associated with the memory system, one or more results associated with at least one of the write parity check or the read parity check.

10. A method, comprising:
receiving, by a memory system from a host system, a write command associated with a first set of data and a first set of parity information;
performing, by the memory system, using a shared write/read parity circuit of the memory system and the first set of parity information, a write parity check for the first set of data;
receiving, by the memory system from the host system, a read command associated with a second set of data and a second set of parity information; and
performing, by the memory system, using the shared write/read parity circuit of the memory system and the second set of parity information, a read parity check for the second set of data.

11. The method of claim 10, further comprising asserting a read enable signal to control an operation of the shared write/read parity circuit.

12. The method of claim 11, wherein performing the write parity check includes performing the write parity check based on an absence of an assertion of the read enable signal at one or more multiplexers associated with the shared write/read parity circuit, and
wherein performing the read parity check includes performing the read parity check based on the assertion of the read enable signal at the one or more multiplexers associated with the shared write/read parity circuit.

13. The method of claim 11, wherein the write command is received by the memory system prior to the read command, and
wherein the method further comprises:
writing, by the memory system, the first set of data and the first set of parity information to one or more memory components associated with the memory system based on the first set of data passing the write parity check; and
asserting, by the memory system, the read enable signal a time period after writing the first set of data and the first set of parity information to the one or more memory components.

14. The method of claim 11, wherein the read command is received by the memory system prior to the write command, and
wherein the method further comprises:
reading, by the memory system, the second set of data and the second set of parity information from one or more memory components associated with the memory system; and
asserting the read enable signal based on receiving the read command.

15. The method of claim 11, wherein the shared write/read parity circuit includes a flip-flop component and an associated multiplexer, and
wherein the method further comprises selectively routing, by the memory system to the flip-flop component, one of a first data input associated with the write command or a second data input associated with the read command based on whether the read enable signal is asserted at the multiplexer.

16. The method of claim 11, wherein the shared write/read parity circuit includes a parity result latch and an associated multiplexer, and
wherein the method further comprises selectively routing, by the memory system to the parity result latch, one of a first data input associated with the write command or a second data input associated with the read command based on whether the read enable signal is asserted at the multiplexer.

17. The method of claim 10, wherein the shared write/read parity circuit is associated with a read data latch and a write data latch,
wherein performing the write parity check includes performing the write parity check based on a write clock signal asserted at the write data latch, and
wherein performing the read parity check includes performing the read parity check based on a read clock signal asserted at the read data latch.

18. The method of claim 10, further comprising transmitting, by the memory system to the host system and via at least one of a data error pad associated with the memory system or a data parity pad associated with the memory system, one or more results associated with at least one of the write parity check or the read parity check.

19. A high bandwidth memory (HBM) system, comprising:
a shared write/read parity circuit; and
one or more memory components operatively coupled to the shared write/read parity circuit,
wherein the HBM system is configured to:
receive, from a host system, a write command associated with a first set of data to be written to the one or more memory components and a first set of parity information associated with the first set of data;
perform, using the shared write/read parity circuit and the first set of parity information, a write parity check for the first set of data;
receive, from the host system, a read command associated with a second set of data to be read from the one or more memory components and a second set of parity information associated with the second set of data; and
perform, using the shared write/read parity circuit and the second set of parity information, a read parity check for the second set of data.

20. The HBM system of claim 19, wherein the HBM system is further configured to assert a read enable signal to control an operation of the shared write/read parity circuit.

21. The HBM system of claim 20, wherein the HBM system, to perform the write parity check, is configured to perform the write parity check based on an absence of an assertion of the read enable signal at one or more multiplexers associated with the shared write/read parity circuit, and
wherein the HBM system, to perform the read parity check, is configured to perform the read parity check based on the assertion of the read enable signal at the one or more multiplexers associated with the shared write/read parity circuit.

22. The HBM system of claim 20, wherein the write command is received by the HBM system prior to the read command, and
wherein the HBM system is further configured to:
write the first set of data and the first set of parity information to the one or more memory components based on the first set of data passing the write parity check; and
assert the read enable signal a time period after writing the first set of data and the first set of parity information to the one or more memory components.

23. The HBM system of claim 20, wherein the read command is received by the HBM system prior to the write command, and
wherein the HBM system is further configured to:
read the second set of data and the second set of parity information from the one or more memory components; and
assert the read enable signal based on receiving the read command.

24. The HBM system of claim 20, wherein the shared write/read parity circuit includes a flip-flop component and an associated multiplexer, and
wherein the HBM system is further configured to selectively route, to the flip-flop component, one of a first data input associated with the write command or a second data input associated with the read command based on whether the read enable signal is asserted at the multiplexer.

25. The HBM system of claim 20, wherein the shared write/read parity circuit includes a parity result latch and an associated multiplexer, and
wherein the HBM system is further configured to selectively route, to the parity result latch, one of a first data input associated with the write command or a second data input associated with the read command based on whether the read enable signal is asserted at the multiplexer.
